(19) United States
(12) Patent Application Publication
(10) Pub. No.: US 2016/0027775 A1
(43) Pub. Date: Jan. 28, 2016

(54) DUAL-WIDTH FIN STRUCTURE FOR FINFETS DEVICES

(71) Applicant: GLOBALFOUNDRIES Inc., Grand Cayman (KY)

(72) Inventors: Murat Kerem AKARVARDAR, Saratoga Springs, NY (US); Ajey P. JACOB, Watervliet, NY (US); Andreas KNORR, Wappingers Falls, NY (US)

(21) Appl. No.: 14/341,423

(22) Filed: Jul. 25, 2014

(51) Int. Cl. H01L 27/088; H01L 29/161; H01L 29/66; H01L 21/02; H01L 21/8234; H01L 29/16; H01L 29/49

(52) U.S. Cl. CPC H01L 27/0886; H01L 29/16; H01L 29/161; H01L 29/495; H01L 29/4966; H01L 21/02532; H01L 21/02164; H01L 21/0217; H01L 21/02238; H01L 21/823431; H01L 21/823412; H01L 29/66545; H01L 21/02255

(57) ABSTRACT

A method of forming a FinFET device having Si or high Ge concentration SiGe fins with a narrow width under the gate and a wider width under the spacer and the resulting device are provided. Embodiments include forming fins; forming a dummy gate, with a dummy oxide thereunder and a nitride HM on top, on the fins, the dummy gate formed perpendicular to the fins; forming a nitride spacer on each side of the dummy gate; forming an oxide in-between adjacent gates and planarizing; removing the nitride HM and dummy gate, forming a channel between the nitride spacers; oxidizing the fins in the channel; removing the dummy oxide and oxidized portions of the fins; and forming a RMG on the fins between the nitride spacers.

### TECHNICAL FIELD

The present disclosure relates to a fin formation process for fin-type field-effect transistor (FinFET) devices. The present disclosure is particularly applicable to 14 nanometer (nm) technology nodes and beyond.

### BACKGROUND

With the increasing miniaturization of integrated circuits (ICs), fin width needs to be scaled in each technology node; however, decreasing the fin width increases the external resistance (Rext) of the device.

An example flow for forming a FinFET device with scaled fins starts with forming the fins 101 and 103, e.g., made of silicon (Si) or silicon germanium (SiGe), as depicted in FIG. 1A. Only two fins are shown in FIG. 1A as an example; however, the proposed method applies to any number of fins including a single fin. The fins 101 and 103 may, for example, be formed to a width of 6 nm to 8 nm. A dummy gate 105 (with an underlying dummy oxide and a nitride hard mask (HM) on the top) is then formed on the fins 101 and 103, as depicted in FIG. 1B. If a bulk substrate is used, shallow trench isolation (STI) formation precedes the dummy gate formation. Adverting to FIG. 1C, nitride spacers 107 and 109 are formed on opposite sides of the dummy gate 105. Next, the spacing between the adjacent gate structures is filled by oxide layers 111 and 113 and planarized to expose the nitride HM on top of the dummy gate structures (selective epi and high temperature activation anneal for source-drain formation after spacer is skipped for simplicity). Subsequent to hard mask removal, the dummy gate 105 is removed forming a channel with the dummy oxide 115 remaining over the fins 101 and 103, as depicted in FIG. 1D. Thereafter, a replacement metal gate (RMG) (not shown for illustrative convenience) is formed on the fins 101 and 103 between the nitride spacers 107 and 109, and the remainder of the RMG process continues. Consequently, the width of the fins 101 and 103 is the same under both the RMG and the nitride spacers 107 and 109.

Since the considered fin widths for advanced FinFET technologies are well below 10 nm, the ungated portion of the fins under the spacers result in a very high external resistance. On the other hand, the fin width under the gate should be kept very narrow to guarantee an adequate electrostatic integrity for very short channel (10-20 nm) devices. A need therefore exists for methodology enabling a narrow fin width under the gate and a wider width under the spacers and the resulting device.

### SUMMARY

An aspect of the present disclosure is a method of forming fins of Si or high Ge concentration SiGe with a narrow width under the gate and a wider width under the spacers.

Another aspect of the present disclosure is a FinFET device having Si or high Ge concentration SiGe fins with a narrow width under the gate and a wider width under the spacers.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming Si fins; forming a dummy gate, with a dummy oxide thereunder and a nitride HM on top, on the Si fins, the dummy gate formed perpendicular to the Si fins; forming a nitride spacer on each side of the dummy gate; filling oxide in-between adjacent gates and planarizing the oxide; removing the nitride HM and dummy gate, forming a channel between the nitride spacers; oxidizing the Si fins in the channel; removing the dummy oxide and oxidized portions of Si fins; and forming a RMG on the Si fins between the nitride spacers.

Aspects of the present disclosure include forming Si fins to a width of 10 nm to 20 nm. Further aspects include oxidizing the Si fins until each of the Si fins has a width of 6 nm to 8 nm in the channel. Another aspect includes oxidizing the Si fins at a temperature of 800° C. to 1000° C.

Another aspect of the present disclosure is a method including: forming SiGe fins; forming a dummy gate, with a dummy oxide thereunder and a nitride HM on top, on the SiGe fins, the poly dummy gate formed perpendicular to the SiGe fins; forming a nitride spacer on each side of the dummy gate; filling oxide in-between adjacent gates and planarizing the oxide; removing the nitride HM and dummy gate, forming a channel between the nitride spacers; oxidizing the SiGe fins in the channel so that the Ge percentage increases due to condensation; removing the dummy oxide and oxidized portions of the SiGe fins; and forming a RMG on the SiGe fins between the nitride spacers.

Aspects of the present disclosure include forming the SiGe fins with 15% to 40% Ge. Other aspects include forming the SiGe fins to a width of 10 nm to 20 nm. Another aspect includes oxidizing the SiGe fins until each of the SiGe fins has a width of 6 nm to 8 nm in the channel. Additional aspects include oxidizing the SiGe fins at a temperature of 800° C. to 950° C. Other aspects include oxidizing the SiGe fins for 2 mins. to 60 mins. depending on the temperature and initial Ge %. Further aspects include condensing the SiGe fins until the concentration of Ge is 30% to 80%.

Another aspect of the present disclosure is a device including: fins, each fin having a first portion between two second portions, the first portion having a narrower width than the second portions; a RMG formed on the first portion of the fins; and a nitride spacer on each side of the RMG on the second portions. Aspects of the device include the first portion being formed to a width of 6 nm to 8 nm and the second portions being formed to a width of 10 nm to 20 nm. Other aspects include the fins being formed of silicon Si. Further aspects include the fins being formed of SiGe. Another aspect includes the concentration of Ge relative to Si being 30% to 80%.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1D schematically illustrate a top view of sequential steps of a background method of forming a FinFET device having narrow fins under both the gate and the gate spacers; and

FIGS. 2 through 7 schematically illustrate a top view of sequential steps of a method of forming a FinFET device having fins with a narrow width under the gate and a wider width under the gate spacers, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of increased Rext upon forming FinFet devices with a scaled fin width. When applied to fins made of low percentage (10-40%) SiGe, the proposed method allows an increase in Ge % to 70-80% by condensation in addition to decreasing the external resistance.

Methodology in accordance with embodiments of the present disclosure includes forming Si fins. A dummy gate (with a dummy oxide underneath and a nitride HM on top) is formed on the Si fins, the dummy gate formed perpendicular to the Si fins. A nitride spacer is formed on each side of the dummy gate. Oxide is filled in-between adjacent gates and planarized and the nitride HM and dummy gate are removed, forming a channel between the nitride spacers. The Si fins are oxidized in the channel. The dummy oxide and oxidized portions of the Si fins are removed, and a RMG is formed on the Si fins between the nitride spacers.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

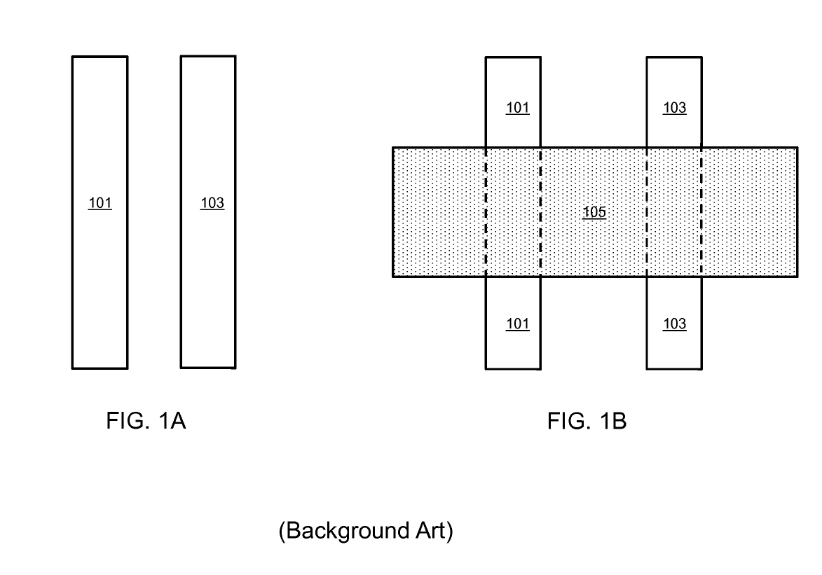

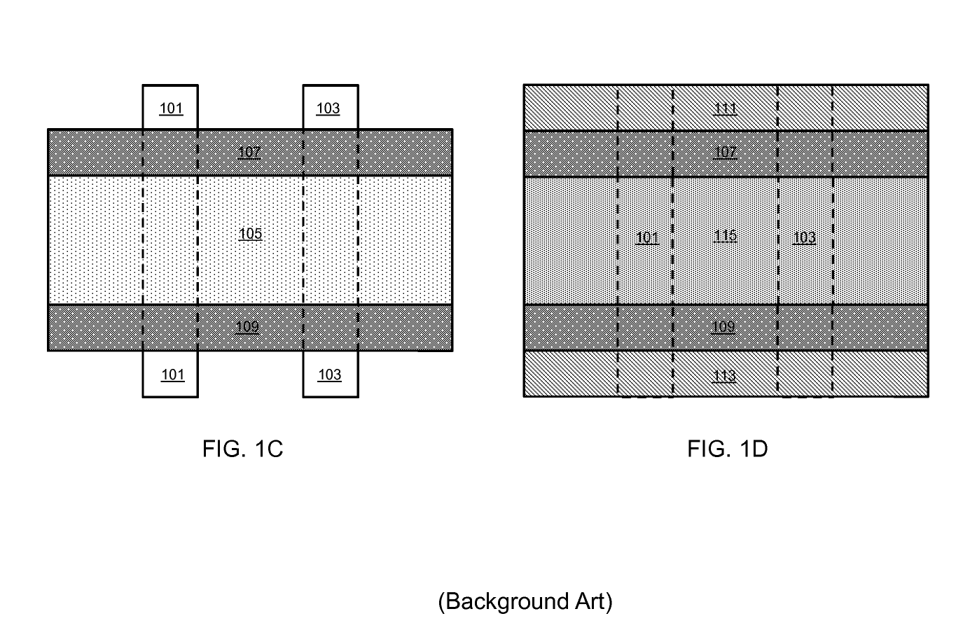

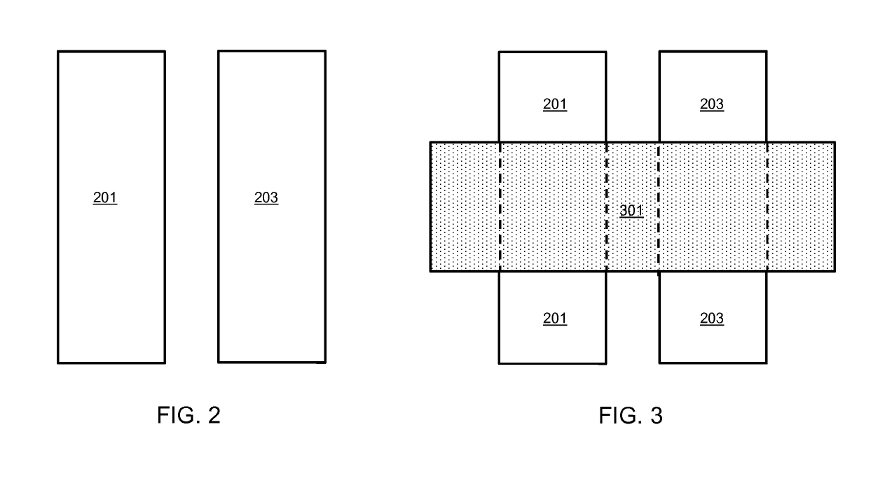

Adverting to FIG. 2, fins 201 and 203, e.g., of Si or low Ge concentration SiGe, are formed by increasing the spacer image transfer (SIT) thickness and reducing the mandrel critical dimension (CD) over the SIT thickness and mandrel CD in forming the fins 101 and 103 in FIG. 1A. In particular, the fins 201 and 203 may, for example, be formed to a width of 10 nm to 20 nm with a SIT spacer 5 nm to 10 nm bigger than the respective fin width depending on etch bias. Likewise, the mandrel CD may be reduced, for example, by the fin width difference (wide fin CD-narrow fin CD) if etch bias is zero. In addition, in the case where the fins 201 and 203 are formed of low Ge concentration SiGe, the fins 201 and 203 may, for example, be formed with 10% to 40% Ge.

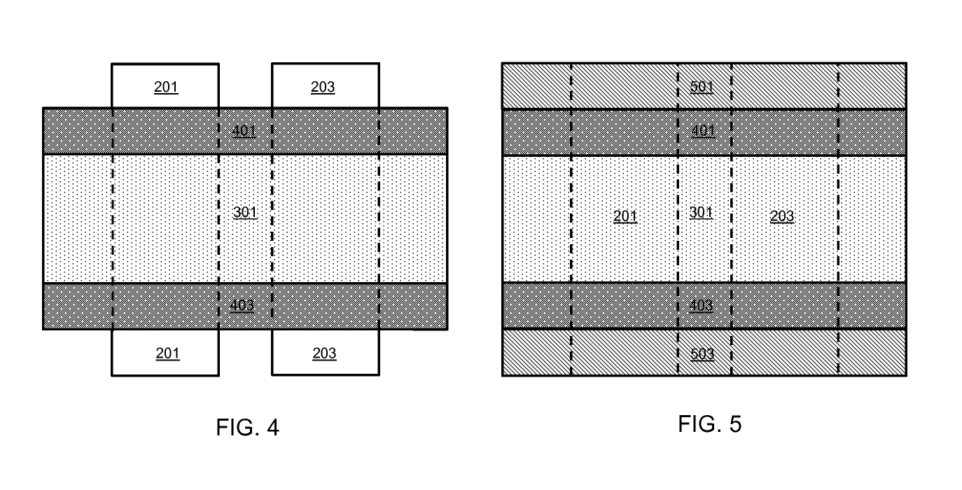

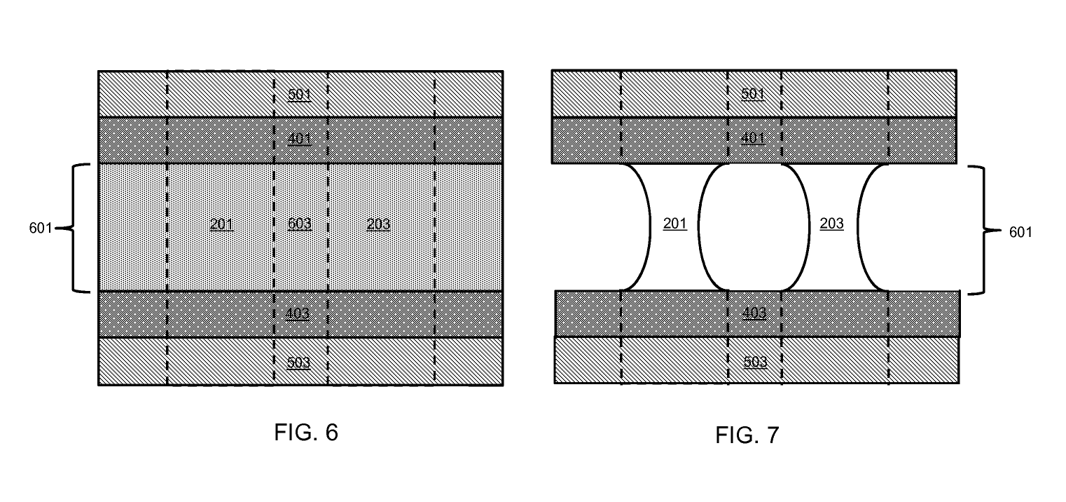

Next, a dummy gate 301 (with a dummy oxide underneath and a nitride HM on top) is formed on the fins 201 and 203, perpendicular to the fins 201 and 203, as depicted in FIG. 3. Spacers 401 and 403, e.g., of nitride, are then formed on opposite sides of the dummy gate 301, as depicted in FIG. 4. Next, oxides 501 and 503 are formed in-between adjacent gates (not shown for illustrative convenience) and planarized, as depicted in FIG. 5. The oxides 501 and 503 may, for example, be formed of high-density plasma (HDP) oxide or flowable oxide. Thereafter, the dummy gate 301 and nitride HM are removed by combining RIE and wet etches, for example, forming a channel 601 between the spacers 401 and 403, as depicted in FIG. 6, with the dummy oxide 603 over the fins 201 and 203 in channel 601.

Adverting to FIG. 7, the fins 201 and 203 may, for example, be partially oxidized in the channel 601 until the final fin width is 6 nm to 8 nm. In particular, the fins 201 and 203 may, for example, be partially oxidized by either a dry or wet oxidation, though dry oxidation is more controllable. Then the oxidized portions and dummy oxide 603 are removed by COR, Siconi™—a remote plasma assisted dry etch process, or DHF wet etching, e.g., COR or Siconi™. Thereafter, a RMG (not shown for illustrative convenience) is formed on the fins 201 and 203 between the nitride spacers 401 and 403, and the remainder of the RMG process continues.

In the case where the fins 201 and 203 are formed of Si, the fins 201 and 203 may, for example, be oxidized at a temperature of 800° C. to 1000° C. for 3 mins. to 30 mins. In the case where the fins 201 and 203 are formed of SiGe, the fins 201 and 203 may, for example, be oxidized at a temperature of 800° C. to 950° for 2 mins. to 60 mins. depending on the temperature and initial Ge %, since the oxidation results in condensation of the Ge such that the Ge concentration increases. In other words, in the case where the fins 201 and 203 are composed of SiGe, the fins 201 and 203 may, for example, be oxidized and, therefore, condensed until the concentration of Ge is increased to 30% to 80% (not shown for illustrative convenience). In particular, whereas high Ge concentration SiGe fins are often subjected to harsh STI densification anneals, e.g., greater than 1000° C. for 30 mins. to 60 mins., as well as an activation anneal, e.g., greater than 1000° C. for a few seconds, the thermal budget post condensation at the RMG module is less than 450° C. Consequently, the initial low Ge concentration of fins 201 and 203, for example, can be increased late in the process flow such that some of the thermal budget related issues are mitigated and compatibility with the silicon baseline is maximized.

The embodiments of the present disclosure can achieve several technical effects including a scaled fin width under the gate and a wider fin width under the gate spacers to simultaneously meet good electrostatics and low external resistance. In addition, high Ge concentration SiGe fins may be achieved while mitigating thermal budget related issues. Embodiments of the present disclosure enjoy utility in various industrial applications as, for example, microprocessors, smart phones, mobile phones, cellular handsets, set-top boxes, DVD recorders and players, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming silicon (Si) fins;
forming a dummy gate, with a dummy oxide thereunder and a nitride hard mask (HM) on top, on the Si fins, the dummy gate formed perpendicular to the Si fins;
forming a nitride spacer on each side of the dummy gate;
filling oxide between adjacent gates and planarizing the oxide;
removing the nitride HM and dummy gate, forming a channel between the nitride spacers;
oxidizing the Si fins in the channel;
removing the dummy oxide and oxidized portions of the Si fins; and
forming a replacement metal gate (RMG) on the Si fins between the nitride spacers.

2. The method according to claim 1, comprising forming the Si fins to a width of 10 nanometers (nm) to 20 nm.

3. The method according to claim 1, comprising oxidizing the Si fins until each of the Si fins has a width of 6 nm to 8 nm in the channel.

4. The method according to claim 3, comprising oxidizing the Si fins at a temperature of 800° C. to 1000° C.

5. A method comprising:
forming silicon germanium (SiGe) fins;
forming a dummy gate, with a dummy oxide thereunder and a nitride hard mask (HM) on top, on the SiGe fins, the poly dummy gate formed perpendicular to the SiGe fins;
forming a nitride spacer on each side of the dummy gate;
filling oxide in-between adjacent gates and planarizing the oxide;
removing the dummy gate, forming a channel between the nitride spacers;
oxidizing the SiGe fins in the channel;
condensing the germanium (Ge);
removing the dummy oxide and oxidized portions of the SiGe fins; and
forming a replacement metal gate (RMG) on the SiGe fins between the nitride spacers.

6. The method according to claim 5, comprising forming the SiGe fins with 15% to 40% Ge.

7. The method according to claim 5, comprising forming the SiGe fins to a width of 10 nanometers (nm) to 20 nm.

8. The method according to claim 5, comprising oxidizing the SiGe fins until each of the SiGe fins has a width of 6 nm to 8 nm in the channel and a Ge % between 40 and 80%.

9. The method according to claim 5, comprising oxidizing the SiGe fins at a temperature of 800° C. to 950° C.

10. The method according to claim 5, comprising oxidizing the SiGe fins for 2 minutes to 60 minutes depending on temp and initial Ge %.

11. The method according to claim 5, comprising condensing the SiGe fins until the concentration of Ge is 30% to 80%.

12. A device comprising:
fins, each fin having a first portion between two second portions, the first portion having a narrower width than the second portions;
a replacement metal gate (RMG) formed on the first portion of the fins; and
a nitride spacer on each side of the RMG on the second portions.

13. The device according to claim 12, wherein the first portion has a width of 6 nanometers (nm) to 8 nm and the second portions each have a width of 10 nm to 20 nm.

14. The device according to claim 12, wherein the fins are formed of silicon (Si).

15. The device according to claim 12, wherein the fins are formed of silicon germanium (SiGe).

16. The device according to claim 12, wherein the concentration of germanium (Ge) relative to Si is 30% to 80%.
